(19) United States
(12) Patent Application Publication
(10) Pub. No.: US 2016/0190368 A1
(43) Pub. Date: Jun. 30, 2016

(54) Photovoltaic Device and Method of Making

(71) Applicant: FIRST SOLAR MALAYSIA SDN. BHD., Kulim (MY)

(72) Inventors: Jinbo Cao, Niskayuna, NY (US); Jongwoo Choi, Niskayuna, NY (US); William Hullinger Huber, Niskayuna, NY (US); Qianqian Xin, Shanghai (CN); Sheng Xu, Shanghai (CN)

(73) Assignee: FIRST SOLAR MALAYSIA SDN. BHD., Kulim (MY)

(21) Appl. No.: 14/650,462

(22) PCT Filed: Dec. 9, 2013
(86) PCT No.: PCT/US2013/073869

§ 371 Date: Jun. 8, 2015

(30) Foreign Application Priority Data
Dec. 7, 2012 (CN) 201210524534.5

(51) Int. Cl. H01L 31/0445; H01L 31/0336; H01L 31/18; H01L 31/075

(52) U.S. Cl. CPC H01L 31/0445; H01L 31/075; H01L 31/0336; H01L 31/18

(57) ABSTRACT

A photovoltaic device is presented. The photovoltaic device includes a first semiconductor layer, a second semiconductor layer, and an interlayer disposed between the first semiconductor layer and the second semiconductor layer, wherein the inter layer includes gadolinium. Methods of making photovoltaic devices are also presented.

### BACKGROUND

The invention generally relates to photovoltaic devices. More particularly, the invention relates to photovoltaic devices that include an interlayer, and methods of making the photovoltaic devices.

Thin film solar cells or photovoltaic (PV) devices typically include a plurality of semiconductor layers disposed on a transparent substrate, wherein one layer serves as a window layer and a second layer serves as an absorber layer. The window layer allows the penetration of solar radiation to the absorber layer, where the optical energy is converted to usable electrical energy. The window layer further functions to form a heterojunction (p-n junction) in combination with an absorber layer. Cadmium telluride/cadmium sulfide (CdTe/CdS) heterojunction-based photovoltaic cells are one such example of thin film solar cells, where CdS functions as the window layer.

However, thin film solar cells may have low conversion efficiencies. Thus, one of the main focuses in the field of photovoltaic devices is the improvement of conversion efficiency. Absorption of light by the window layer may be one of the phenomena limiting the conversion efficiency of a PV device. Thus, it is desirable to keep the window layer as thin as possible to help reduce optical losses by absorption. It is also desirable that the thin window layer maintains its structural integrity during the subsequent device fabrication steps, such that the interface between the absorber layer and the window layer contains negligible interface defect states. However, for most of the thin-film PV devices, if the window layer is too thin, a loss in performance can be observed due to low open circuit voltage (V_{OC}) and fill factor (FF).

Thus, there is a need for improved thin film photovoltaic devices configurations, and methods of manufacturing these.

### BRIEF DESCRIPTION OF THE INVENTION

Embodiments of the present invention are included to meet these and other needs. One embodiment is a photovoltaic device. The photovoltaic device includes a first semiconductor layer, a second semiconductor layer, and an interlayer disposed between the first semiconductor layer and the second semiconductor layer, wherein the interlayer includes gadolinium.

One embodiment is a method. The method includes (a) disposing a capping layer on a first semiconductor layer by atomic layer deposition, wherein the capping layer includes magnesium, aluminum, zinc, nickel, gadolinium, or combinations thereof; (b) disposing a second semiconductor layer on the capping layer; and (c) forming an interlayer between the first semiconductor layer and the second semiconductor layer.

One embodiment is a method. The method includes (a) disposing a metallic capping layer on a first semiconductor layer, wherein the metallic capping layer includes magnesium, aluminum, zinc, nickel, gadolinium, or combinations thereof; (b) disposing a second semiconductor layer on the metallic capping layer; and (c) forming an interlayer between the first semiconductor layer and the second semiconductor layer.

One embodiment is a photovoltaic device. The photovoltaic device includes a first semiconductor layer, a second semiconductor layer, and an interlayer disposed between the first semiconductor layer and the second semiconductor layer, wherein the interlayer includes a compound comprising a metal species, sulfur, and oxygen, wherein the metal species includes magnesium, aluminum, zinc, nickel, gadolinium, or combinations thereof.

### DRAWINGS

These and other features, aspects, and advantages of the present invention will become better understood when the following detailed description is read with reference to the accompanying drawings, wherein:

FIG. 1 is a schematic of a photovoltaic device, according to one embodiment of the invention.

FIG. 2 is a schematic of a photovoltaic device, according to one embodiment of the invention.

FIG. 3 is a schematic of a photovoltaic device, according to one embodiment of the invention.

FIG. 4 is a schematic of a semiconductor assembly, according to one embodiment of the invention.

FIG. 5 shows the performance parameters for a photovoltaic device, according to one embodiment of the invention.

FIG. 6 shows the performance parameters for a photovoltaic device, according to one embodiment of the invention.

FIG. 7 shows the performance parameters for a photovoltaic device, according to one embodiment of the invention.

FIG. 8 shows the scanning electron micrographs of a photovoltaic device, according to one embodiment of the invention.

FIG. 9 shows the x-ray photoelectron spectroscopy (XPS) depth profiles of a photovoltaic device, according to one embodiment of the invention.

FIG. 10 shows the x-ray photoelectron spectroscopy (XPS) profiles of a photovoltaic device, according to one embodiment of the invention.

### DETAILED DESCRIPTION

As discussed in detail below, some of the embodiments of the invention include photovoltaic devices including an interlayer disposed between a first semiconductor layer and a second semiconductor layer.

Approximating language, as used herein throughout the specification and claims, may be applied to modify any quantitative representation that could permissibly vary without resulting in a change in the basic function to which it is related. Accordingly, a value modified by a term or terms, such as “about”, and “substantially” is not to be limited to the precise value specified. In some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise.

In the following specification and the claims, the singular forms “a”, “an” and “the” include plural referents unless the context clearly dictates otherwise. As used herein, the term “or” is not meant to be exclusive and refers to at least one of the referenced components (for example, a layer) being present and includes instances in which a combination of the referenced components may be present, unless the context clearly dictates otherwise.

The terms “transparent region” and “transparent layer” as used herein, refer to a region or a layer that allows an average transmission of at least 70% of incident electromagnetic radiation having a wavelength in a range from about 350 nm to about 850 nm.

As used herein, the term “layer” refers to a material disposed on at least a portion of an underlying surface in a continuous or discontinuous manner. Further, the term “layer” does not necessarily mean a uniform thickness of the disposed material, and the disposed material may have a uniform or a variable thickness. As used herein, the term “disposed on” refers to layers disposed directly in contact with each other or indirectly by having intervening layers therebetween, unless otherwise specifically indicated. The term “adjacent” as used herein means that the two layers are disposed contiguously and are in direct contact with each other.

In the present disclosure, when a layer is being described as “on” another layer or substrate, it is to be understood that the layers can either be directly contacting each other or have one (or more) layer or feature between the layers. Further, the term “on” describes the relative position of the layers to each other and does not necessarily mean “on top of” since the relative position above or below depends upon the orientation of the device to the viewer. Moreover, the use of “top,” “bottom,” “above,” “below,” and variations of these terms is made for convenience, and does not require any particular orientation of the components unless otherwise stated.

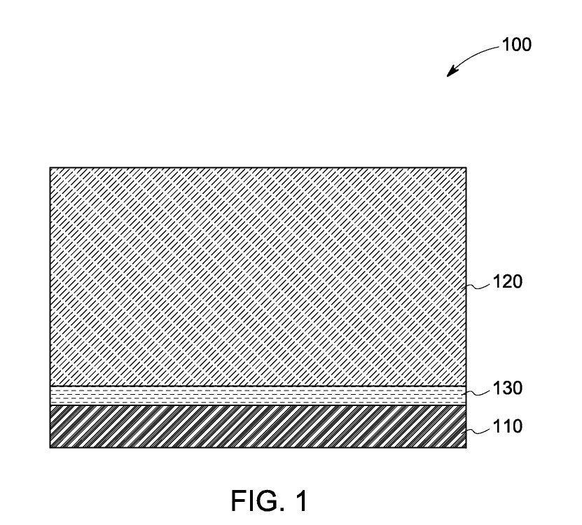

As discussed in detail below, some embodiments of the invention are directed to a photovoltaic device including an interlayer. A photovoltaic device 100, according to one embodiment of the invention, is illustrated in FIGS. 1-3. As shown in FIGS. 1-3, the photovoltaic device 100 includes a first semiconductor layer 110, a second semiconductor layer 120, and an interlayer 130 disposed between the first semiconductor layer 110 and the second semiconductor layer 120.

In some embodiments, as described later, the first semiconductor layer 110 may function as a window layer and the second semiconductor layer 120 may function as an absorber layer. The term “window layer” as used herein refers to a semiconducting layer that is substantially transparent and forms a heterojunction with the absorber layer 120. Non-limiting exemplary materials for the first semiconductor layer 110 include cadmium sulfide (CdS), indium III sulfide (In₂S₃), zinc sulfide (ZnS), zinc telluride (ZnTe), zinc selenide (ZnSe), cadmium selenide (CdSe), oxygenated cadmium sulfide (CdS:O), copper oxide (Cu₂O), zinc oxihydrate (ZnO:H), or combinations thereof. In certain embodiments, the first semiconductor layer 110 includes cadmium sulfide (CdS). In certain embodiments, the first semiconductor layer 110 includes oxygenated cadmium sulfide (CdS:O).

The term “absorber layer” as used herein refers to a semiconducting layer wherein the solar radiation is absorbed. In one embodiment, the second semiconducting layer 120 includes a p-type semiconductor material. In one embodiment, the second semiconducting layer 120 has an effective carrier density in a range from about 1×10¹³ per cubic centimeter to about 1×10¹⁶ per cubic centimeter.

As used herein, the term “effective carrier density” refers to the average concentration of holes and electrons in a material.

In one embodiment, a photoactive material is used for forming the second semiconducting layer 120. Suitable photo-active materials include cadmium telluride (CdTe), cadmium zinc telluride (CdZnTe), cadmium magnesium telluride (CdMgTe), cadmium manganese telluride (CdMnTe), cadmium sulfur telluride (CdSTe), zinc telluride (ZnTe), copper indium disulfide (CIS), copper indium diselenide (CISe), copper indium gallium sulfide (CIGS), copper indium gallium diselenide (CIGSe), copper indium gallium sulfur selenium (CIGSSe), copper indium gallium aluminum sulfur selenium (Cu(In,Ga,Al)(S,Se)₂), copper zinc tin sulfide (CZTS), or combinations thereof. The above-mentioned photo-active semiconductor materials may be used alone or in combination. Further, these materials may be present in more than one layer, each layer having different type of photo-active material or having combinations of the materials in separate layers. In certain embodiments, the second semiconducting layer 120 includes cadmium telluride (CdTe). In certain embodiments, the second semiconducting layer 120 includes p-type cadmium telluride (CdTe).

In some embodiments, the first semiconductor layer 110, the second semiconductor layer 120, or both the layers may contain oxygen. Without being bound by any theory, it is believed that the introduction of oxygen to the first semiconductor layer 110 (e.g., the CdS layer) may result in improved device performance. In some embodiments, the amount of oxygen is less than about 20 atomic percent. In some instances, the amount of oxygen is between about 1 atomic percent to about 10 atomic percent. In some instances, for example in the second semiconductor layer 120, the amount of oxygen is less than about 1 atomic percent. Moreover, the oxygen concentration within the first semiconductor layer 110, the second semiconductor layer 120, or both the layers may be substantially constant or compositionally graded across the thickness of the respective layer.

In some embodiments, the first semiconducting layer 110 and the second semiconducting layer 120 may be doped with a p-type dopant or an n-type dopant to form a heterojunction. As used in this context, a heterojunction is a semiconductor junction that is composed of layers of dissimilar semiconductor material. These materials usually have non-equal band gaps. As an example, a heterojunction can be formed by contact between a layer or region of one conductivity type with a layer or region of opposite conductivity, e.g., a “p-n” junction.

In some embodiments, the first semiconducting layer 110 includes an n-type semiconductor material. In such instances, the second semiconducting layer 120 may be doped to be p-type and the first semiconducting layer 110 and the second semiconducting layer 120 may form an “n-p” heterojunction. In some embodiments, the first semiconducting layer 110 may be doped to be n-type and the second semiconducting layer 120 may be doped such that it effectively forms an n-i-p configuration, using a p+-semiconductor layer on the backside of the second semiconducting layer 120.

As noted earlier, the photovoltaic device 100 further includes an interlayer 130 disposed between the first semiconductor layer 110 and the second semiconductor layer 120. Without being bound by any theory, it is believed that the first semiconductor layer 110 and the second semiconductor layer 120 may form a heterojunction, such as, a “p-n” junction or a “n-i-p” junction with the interlayer 130 positioned between the first semiconductor layer 110 and the second semiconductor layer 120.

In some embodiments, the interlayer 130 includes a metal species. The term “metal species” as used herein refers to elemental metal, metal ions, or combinations thereof. The metal species include magnesium, aluminum, zinc, nickel, gadolinium, or combinations thereof. In some embodiments, the interlayer 130 may include a plurality of the metal species.

In some embodiments, at least a portion of the metal species is present in the interlayer 130 in the form of an elemental metal, a metal alloy, a metal compound, or combinations thereof. In some embodiments, at least a portion of the metal species is present in the interlayer in the form of an elemental metal. In such embodiments, the interlayer 130 includes elemental magnesium, elemental aluminum, elemental zinc, elemental nickel, elemental gadolinium, or combinations thereof. In certain embodiments, the interlayer 130 includes elemental gadolinium.

In some embodiments, at least a portion of the metal species is present in the interlayer in the form of a metal alloy. In some embodiments, the interlayer 130 includes a metal alloy of cadmium and at least one of the metal species, for example, an alloy of cadmium and magnesium. In embodiments wherein the interlayer 130 includes two or more of the metal species, the interlayer 130 may include a metal alloy of two or more of the metal species, for example, an alloy of gadolinium and magnesium. In certain embodiments, the interlayer includes GdₓMg₁₋ₓ, wherein x is an integer greater than 0 and less than 1.

In some embodiments, at least a portion of the metal species is present in the interlayer 130 in the form of a metal compound. The term “metal compound”, as used herein, refers to a macroscopically homogeneous material (substance) consisting of atoms or ions of two or more different elements in definite proportions, and at definite lattice positions. For example, the metal species, sulfur, and oxygen have defined lattice positions in the crystal structure of the compound, in contrast, for example, to an oxygenated metal sulfide where oxygen may be a dopant that is substitutionally inserted on sulfur sites, and not a part of the compound lattice In some embodiments, at least a portion of the metal species is present in the interlayer 130 in the form of a binary metal compound, a ternary metal compound, a quaternary metal compound, or combinations thereof.

In some embodiments, at least a portion of the metal species is present in the interlayer 130 in the form of a binary metal compound, such as, for example, a metal oxide, a metal sulfide, a metal selenide, a metal telluride, or mixtures thereof. Thus, by way of example, in certain embodiments, the interlayer may include magnesium oxide, magnesium sulfide, gadolinium oxide, gadolinium sulfide, or mixtures thereof.

In some embodiments, at least a portion of the metal species is present in the interlayer 130 in the form a metal compound including the metal species, sulfur and oxygen. In some embodiments, the interlayer includes a metal sulfate, a metal sulfite, a metal oxysulfate, or combinations thereof. In certain embodiments, the interlayer 130 includes gadolinium, sulfur, and oxygen. In such instances, the interlayer 130 may include gadolinium sulfate, gadolinium sulfite, gadolinium oxysulfate, or combinations thereof. In certain embodiments, the interlayer 130 includes magnesium, sulfur, and oxygen. In such instances, the interlayer 130 may include magnesium sulfate, magnesium sulfite, magnesium oxysulfate, or combinations thereof.

The interlayer 130 may be further characterized by the concentration of the metal species in the interlayer 130. In some embodiments, an average atomic concentration of the metal species in the interlayer 130 is greater than about 10 percent. In some embodiments, an average atomic concentration of the metal species in the interlayer 130 is greater than about 50 percent. In some embodiments, an average atomic concentration of the metal species in the interlayer 130 is in a range from about 10 percent to about 99 percent. The term “atomic concentration” as used herein refers to the average number of atoms per unit volume. In some embodiments, the interlayer may further include cadmium, sulfur, tellurium, oxygen, or combinations thereof.

The interlayer 130 may be further characterized by a thickness. In some embodiments, the interlayer 130 has a thickness in a range from about 0.2 nanometers to about 20 nanometers. In some embodiments, the interlayer 130 has a thickness in a range from about 0.2 nanometers to about 10 nanometers. In some embodiments, the interlayer 130 has a thickness in a range from about 1 nanometer to about 5 nanometers. In some embodiments, it may be desirable to have a thin interlayer, such that there are minimal optical losses in the interlayer due to absorption.

As noted earlier, the thickness of the window layer 110 is typically desired to be minimized in a photovoltaic device to achieve high efficiency. With the presence of the interlayer 130, the thickness of the first semiconductor layer 110 (e.g., CdS layer) may be reduced to improve the performance of the present device.

Moreover, the present device may achieve a reduction in cost of production because of the use of lower amounts of CdS.

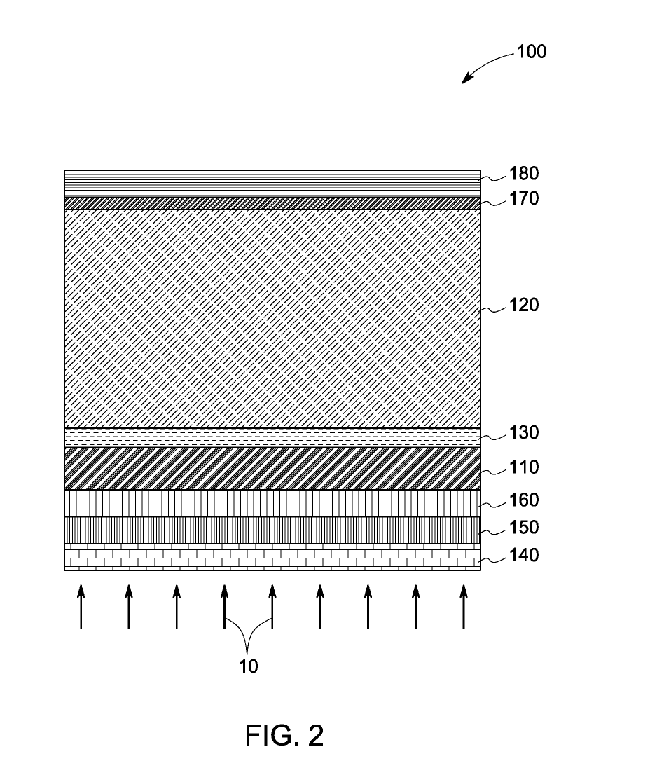

As noted earlier, the interlayer 130 is a component of a photovoltaic device 100. In some embodiments, the photovoltaic device includes a “superstrate” configuration of layers. In such embodiments, the photovoltaic device 100 further includes a support 140, and a transparent conductive layer 150 (sometimes referred to in the art as a front contact layer) is disposed on the support 110, as indicated in FIG. 2. As illustrated in FIG. 2, in such embodiments, the solar radiation 10 enters from the support 140, and after passing through the transparent conductive layer 150, the first semiconductor layer 110, and the interlayer 130, enters the second semiconductor layer 120, where the conversion of electromagnetic energy of incident light (for instance, sunlight) to electron-hole pairs (that is, to free electrical charge) occurs.

In some embodiments, the support 140 is transparent over the range of wavelengths for which transmission through the support 140 is desired. In one embodiment, the support 140 may be transparent to visible light having a wavelength in a range from about 400 nm to about 1000 nm. In some embodiments, the support 140 includes a material capable of withstanding heat treatment temperatures greater than about 600° C., such as, for example, silica or borosilicate glass. In some other embodiments, the support 140 includes a material that has a softening temperature lower than 600° C., such as, for example, soda-lime glass or a polyimide. In some embodiments certain other layers may be disposed between the transparent conductive layer 150 and the support 140, such as, for example, an anti-reflective layer or a barrier layer (not shown).

In some embodiments, the transparent conductive layer 150 includes a transparent conductive oxide (TCO). Non-limiting examples of transparent conductive oxides include cadmium tin oxide (CTO), indium tin oxide (ITO), fluorine-doped tin oxide (SnO:F or FTO), indium-doped cadmium-oxide, cadmium stannate (Cd₂SnO₄ or CTO), doped zinc oxide (ZnO), such as aluminum-doped zinc-oxide (ZnO:Al or AZO), indium-zinc oxide (IZO), and zinc tin oxide (ZnSnOₓ), or combinations thereof. Depending on the specific TCO employed and on its sheet resistance, the thickness of the transparent conductive layer 150 may be in a range of from about 50 nm to about 600 nm, in one embodiment.

In some embodiments, the first semiconductor layer 110 is disposed directly on the transparent conductive layer 150 (embodiment not shown). In alternate embodiments, the photovoltaic device 100 includes an additional buffer layer 160 interposed between the transparent conductive layer 150 and the first semiconductor layer 110, as indicated in FIG. 2. In some embodiments, the thickness of the buffer layer 160 is in a range from about 50 nm to about 200 nm. Non-limiting examples of suitable materials for the buffer layer 160 include tin dioxide (SnO₂), zinc tin oxide (zinc-stannate (ZTO)), zinc-doped tin oxide (SnO₂:Zn), zinc oxide (ZnO), indium oxide (In₂O₃), or combinations thereof.

In some embodiments, the photovoltaic device 100 may further include a p+-type semiconductor layer 170 disposed on the second semiconductor layer 120, as indicated in FIG. 2. The term “p+-type semiconductor layer” as used herein refers to a semiconductor layer having an excess mobile p-type carrier or hole density compared to the p-type charge carrier or hole density in the second semiconductor layer 120. In some embodiments, the p+-type semiconductor layer has a p-type carrier density in a range greater than about 1×10¹⁶ per cubic centimeter. The p+-type semiconductor layer 170 may be used as an interface between the second semiconductor layer 120 and the back contact layer 180, in some embodiments.

In one embodiment, the p+-type semiconductor layer 170 includes a heavily doped p-type material including amorphous Si:H, amorphous SiC:H, crystalline Si, microcrystalline Si:H, microcrystalline SiGe:H, amorphous SiGe:H, amorphous Ge, microcrystalline Ge, GaAs, BaCuSF, BaCuSeF, BaCuTeF, LaCuOS, LaCuOSe, LaCuOTe, LaSrCuOS, LaCuOSe_{0.6}Te_{0.4}, BiCuOSe, BiCaCuOSe, PrCuOSe, NdCuOS, Sr₂Cu₂ZnO₂S₂, Sr₂CuGaO₃S, (Zn,Co,Ni)Oₓ, or combinations thereof. In another embodiment, the p+-type semiconductor layer 170 includes a p+-doped material including zinc telluride, magnesium telluride, manganese telluride, beryllium telluride, mercury telluride, arsenic telluride, antimony telluride, copper telluride, or combinations thereof. In some embodiments, the p+-doped material further includes a dopant including copper, gold, nitrogen, phosphorus, antimony, arsenic, silver, bismuth, sulfur, sodium, or combinations thereof.

In some embodiments, the photovoltaic device 100 further includes a back contact layer 180, as indicated in FIG. 2. In some embodiments, the back contact layer 180 is disposed directly on the second semiconductor layer 120 (embodiment not shown). In some other embodiments, the back contact layer 180 is disposed on the p+-type semiconductor layer 170 disposed on the second semiconductor layer 120, as indicated in FIG. 2. In some embodiments, the back contact layer 180 includes gold, platinum, molybdenum, tungsten, tantalum, palladium, aluminum, chromium, nickel, silver, graphite, or combinations thereof. In certain embodiments, another metal layer (not shown), for example, aluminum, may be disposed on the metal layer 180 to provide lateral conduction to the outside circuit.

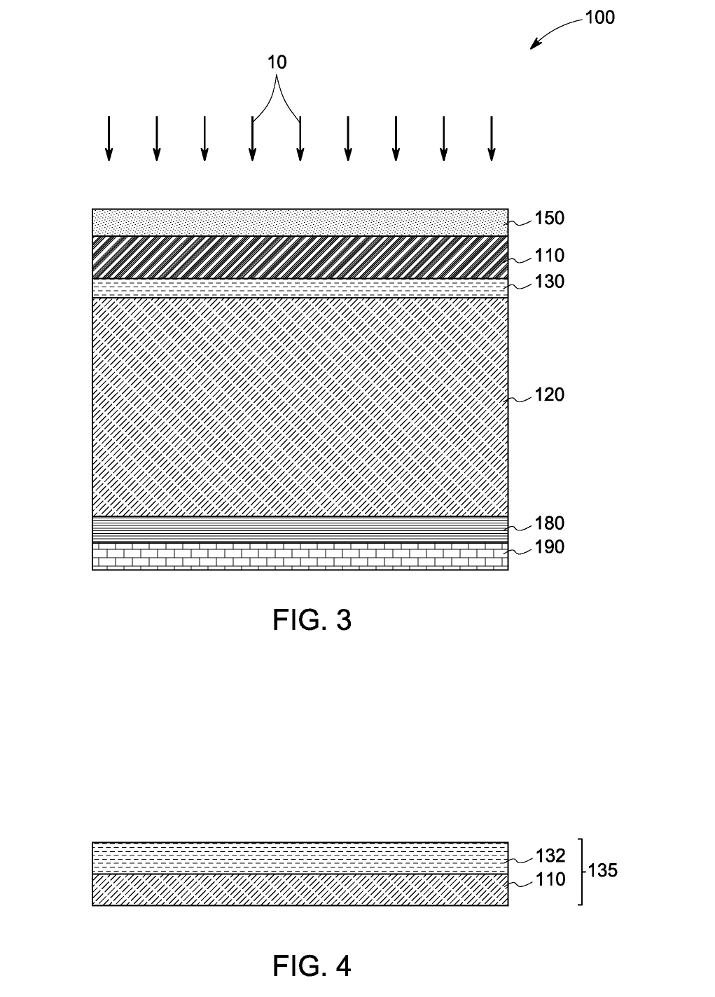

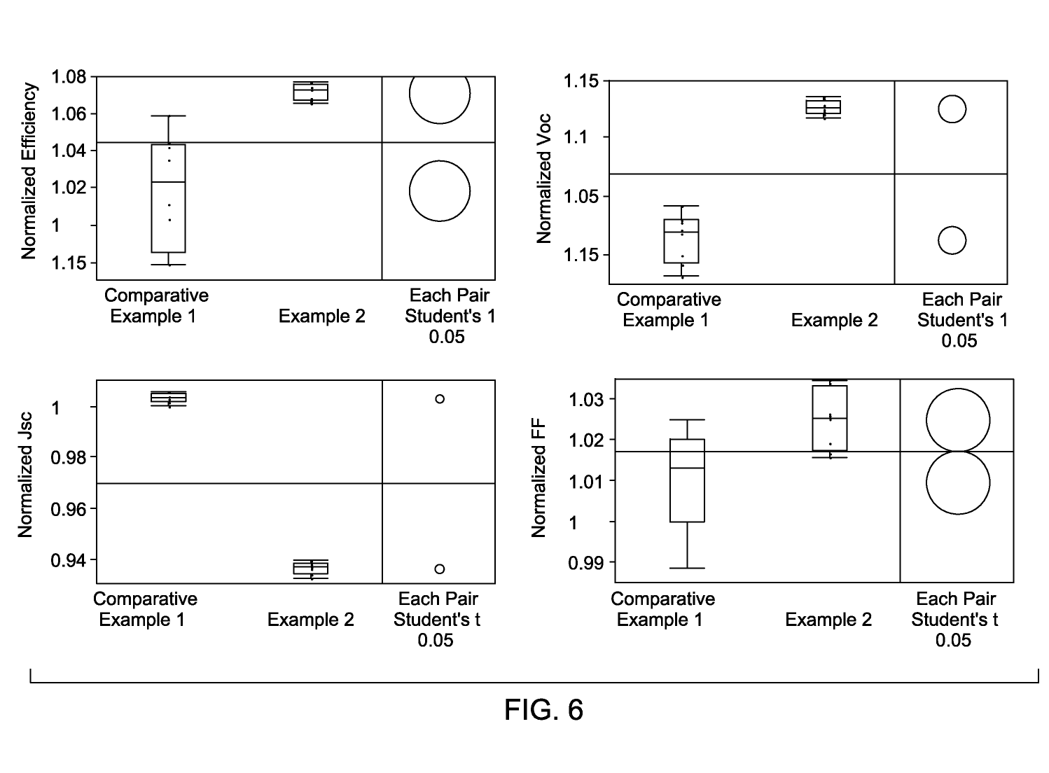

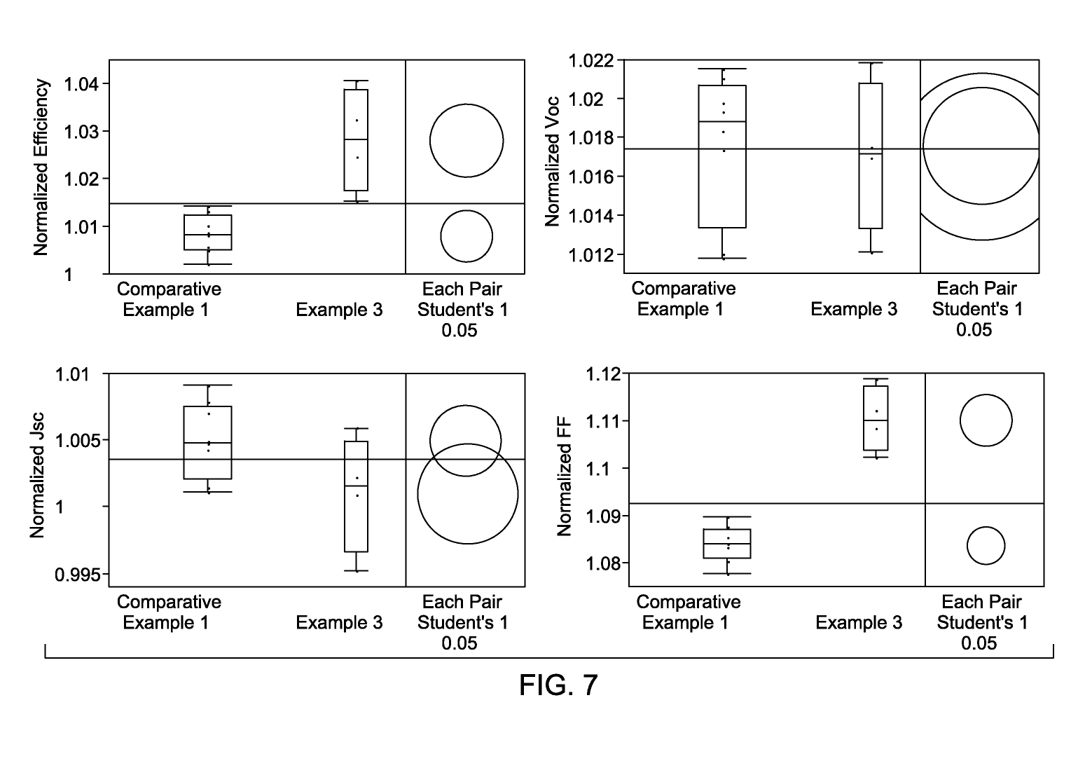

In alternative embodiments, as illustrated in FIG. 3, a photovoltaic device 100 including a “substrate” configuration is presented. The photovoltaic device 100 includes a back contact layer 180 disposed on a support 190. Further, the second semiconductor layer 120 is disposed on the back contact layer 180, and the interlayer 130 as described herein earlier, is disposed on the second semiconductor layer 120. The first semiconductor layer 110 is disposed on the interlayer 130, and the transparent conductive layer 150 is further disposed on the first semiconductor layer 110, as indicated in FIG. 6. As illustrated in FIG. 3, in such embodiments, the solar radiation 10 enters from the transparent conductive layer 150 and after passing through the first semiconductor layer 110, and the interlayer 130, enters the second semiconductor layer 120, where the conversion of electromagnetic energy of incident light (for instance, sunlight) to electron-hole pairs (that is, to free electrical charge) occurs.

In some embodiments, the composition of the layers illustrated in FIG. 3, such as, the substrate 110, the transparent conductive layer 150, the first semiconductor layer 110, the interlayer 130, the second semiconductor layer 120, and the back contact layer 180 may have the same composition as described above in FIG. 3 for the superstrate configuration

Some embodiments include a method of making a photovoltaic device. The method generally includes disposing the interlayer 130 between the first semiconductor layer 110 and the second semiconductor layer 120. As understood by a person skilled in the art, the sequence of disposing the three layers or the whole device may depend on a desirable configuration, for example, “substrate” or “superstrate” configuration of the device.

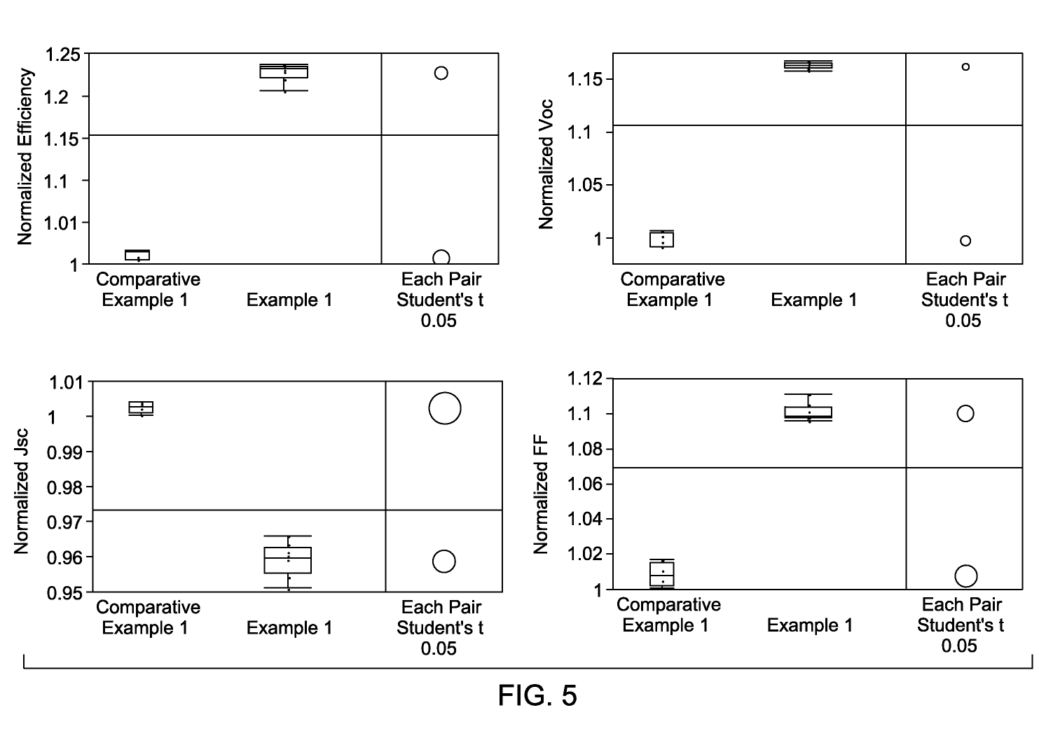

In certain embodiments, a method for making a photovoltaic device in superstrate configuration is described. Referring now to FIG. 4, in some embodiments, the method includes disposing a capping layer 132 on a first semiconductor layer 110 to form a semiconductor assembly 135. The capping layer 132 includes magnesium, aluminum, zinc, nickel, gadolinium, or combinations thereof. In some embodiments, the capping layer 132 includes an oxide of magnesium, aluminum, zinc, nickel, gadolinium, or combinations thereof. In certain embodiments, the capping layer 132 includes magnesium oxide, gadolinium oxide, or combinations thereof.

In some embodiments, the method includes disposing a metallic capping layer 132 on the first semiconductor layer 110. The term “metallic capping layer” as used herein refers to a capping layer include at least one elemental metal. In some embodiments, the metallic capping layer 132 includes elemental magnesium, elemental aluminum, elemental zinc, elemental nickel, elemental gadolinium, or combinations thereof. In some embodiments, the metallic capping layer 132 includes a metallic alloy including magnesium, aluminum, zinc, nickel, gadolinium, or combinations thereof. In certain embodiments, the metallic capping layer 132 includes magnesium, gadolinium, or combinations thereof.

The capping layer 132 may be disposed on the first semiconductor layer 110 using a suitable deposition technique, such as, for example, sputtering, atomic layer deposition, or combinations thereof. In certain embodiments, the method includes disposing the capping layer 132 on the first semiconductor layer 110 by atomic layer deposition (ALD). Without being bound by any theory, it is believed that deposition of the capping layer 132 by ALD may provide for a more conformal layer in comparison to other deposition methods. A conformal layer may provide for a more uniform contact of the subsequent interlayer with the first semiconductor layer 110 and the second semiconductor layer 120. Further, deposition of the capping layer by ALD may provide for an interlayer 130 having lower number of pinholes when compared to layers deposited using other deposition techniques.

The method further includes disposing a second semiconductor layer 120 on the capping layer 132. In one embodiment, the second semiconductor layer 120 may be deposited using a suitable method, such as, close-space sublimation (CSS), vapor transport deposition (VTD), ion-assisted physical vapor deposition (IAPVD), radio frequency or pulsed magnetron sputtering (RFS or PMS), plasma enhanced chemical vapor deposition (PECVD), or electrochemical deposition (ECD).

The method further includes forming an interlayer 130 between the first semiconductor layer 110 and the second semiconductor layer 120. The interlayer composition and configuration are as described earlier. The step of forming the interlayer 132 may be effected prior to, simultaneously with, or after the step of disposing the second semiconductor layer 120 on the capping layer 132.

In some embodiments, the step of interlayer 130 formation may further include intermixing of at least a portion of the interlayer metal species with at least portion of the first semiconductor layer 110 material, the second semiconductor layer 120 material, or both. In some instances, the method may result in formation of metal alloys during the interlayer 130 formation. In some instances, the method may further result in formation of oxides, sulfites, sulfates, sulfites, or oxy-sulfates, of the metal species during the interlayer 130 formation. Without being bound by any theory, it is believed that during the annealing step, the CdTe-deposition step, or the post-deposition processing steps, recrystallization and chemical changes may occur in the interlayer 130, and a metal compound (for example, oxide, sulfate or oxy-sulfate) may be formed in the interlayer 130.

In some embodiments, the interlayer 130 may be formed prior to the step of disposing the second semiconductor layer 120. In such instances, the method may further include, a step of thermally processing the semiconductor assembly 135 including the capping layer 132 disposed on the first semiconductor layer 110, as indicated in FIG. 4. The step of thermal processing may include, for example, annealing of the semiconductor assembly 135.

In some embodiments, the annealing step, may be carried out in an environment including an inert gas, oxygen, air, or combinations thereof. The annealing may be carried out under a suitable pressure in a range from about 1 mTorr to about 760 Torr. In certain instances, the annealing pressure may be in a range from about 1 Torr to about 500 Torr. The semiconductor assembly may be annealed at a temperature in a range from about 500 degrees Celsius to about 700 degrees Celsius, and in certain instances, in a range from about 550 degrees Celsius to about 650 degrees Celsius. The annealing may be further carried out for a suitable duration, for example, in a range from about 10 minutes to about 30 minutes.

In some embodiments, the method includes thermally processing a plurality of semiconductor assemblies in a face-to-face configuration. The method may include thermally processing a first semiconductor assembly including an interlayer disposed on a first semiconductor layer and thermally processing a second semiconductor assembly including another interlayer disposed on a first semiconductor layer. In one embodiment, the two assemblies are thermally processed simultaneously, and the semiconductor assemblies are arranged such that the two interlayers face each other with a gap between them, during the thermal processing.

In some embodiments, the method further includes disposing at least one spacer between the interlayers, such that the layers are spaced apart from one another during the thermal processing. Generally speaking, any suitable spacer having the required structural characteristics capable of withstanding the thermal processing conditions (as described previously) may be used for separating the first semiconductor assembly and the second semiconductor assembly, and for maintaining a desired gap between the two assemblies.

In some other embodiments, the interlayer 130 may be formed simultaneously with the step of disposing the second semiconductor layer 120, for example, during the high-temperature deposition of CdTe. In some embodiments, the interlayer 130 may be formed after the step of disposing the second semiconductor layer 120, for example, during the cadmium chloride treatment step, during the p+-type layer formation step, during the back contact formation step, or combinations thereof.

Without being bound by any theory, it is believed that the capping layer 132 may preclude sublimation of the semiconductor material in the first semiconductor layer 110, during the thermal processing step or the second semiconductor layer 120 deposition step. In instances wherein the first semiconductor layer includes CdS, the capping layer may preclude sublimation of the CdS material during the CdS annealing step or the CdTe deposition step. Accordingly, use of the capping layer 132 may provide for a smoother CdS layer, and improved junction formation between CdS and CdTe, resulting in improved performance parameters. Moreover, the method may provide for reduction in cost of production, because of lower CdS loss during processing, allowing for a thin CdS layer to be employed.

As noted earlier, the photovoltaic device may further include one or more additional layers, for example, a support 140, a transparent conductive layer 150, a buffer layer 160, a p+-type semiconductor layer 170, and a back contact layer 180, as depicted in FIG. 2. The method further includes, in some embodiments, the step of disposing a first semiconductor layer 110 on a transparent conductive layer 150. Non-limiting examples of the deposition methods for the window layer 150 include one or more of close-space sublimation (CSS), vapor transport deposition (VTD), sputtering (for example, direct current pulse sputtering (DCP), electro-chemical deposition (ECD), and chemical bath deposition (CBD).

In some embodiments, the method further includes disposing the transparent conductive layer 150 on a support 110, as indicated in FIG. 2. The transparent conductive layer 150 is disposed on the support 110 by any suitable technique, such as sputtering, chemical vapor deposition, spin coating, spray coating, or dip coating. Referring to FIG. 2, in some embodiments, an optional buffer layer 160 may be deposited on the transparent conductive layer 150 using sputtering.

Referring again to FIG. 2, a p+-type semiconducting layer 170 may be further disposed on the second semiconductor layer 120 by depositing a p+-type material using any suitable technique, for example PECVD, in one embodiment. In an alternate embodiment, a p+-type semiconductor layer 170 may be disposed on the second semiconductor layer 120 by chemically treating the second semiconductor layer 120 to increase the carrier density on the back-side (side in contact with the metal layer and opposite to the window layer) of the second semiconductor layer 120. In one embodiment, the photovoltaic device 100 may be completed by depositing a back contact layer, for example, a metal layer 180 on the p+-type semiconductor layer 170.

One or more of the first semiconductor layer 110, the second semiconductor layer 120, the back contact layer 180, or the p+type layer 170 (optional) may be further heated or subsequently treated (for example, annealed) after deposition to manufacture the photovoltaic device 100.

In some embodiments, other components (not shown) may be included in the exemplary photovoltaic device 100, such as, buss bars, external wiring, laser etches, etc. For example, when the device 100 forms a photovoltaic cell of a photovoltaic module, a plurality of photovoltaic cells may be connected in series in order to achieve a desired voltage, such as through an electrical wiring connection. Each end of the series connected cells may be attached to a suitable conductor such as a wire or bus bar, to direct the generated current to convenient locations for connection to a device or other system using the generated current. In some embodiments, a laser may be used to scribe the deposited layers of the photovoltaic device 100 to divide the device into a plurality of series connected cells.

### EXAMPLES

### Comparative Example 1

### Method Of Manufacturing A Cadmium Telluride Photovoltaic Device, Without An Interlayer

A cadmium telluride photovoltaic device was made by depositing several layers on a cadmium tin oxide (CTO) transparent conductive oxide (TCO)-coated coated substrate. The substrate was a 1.3 millimeters thick CIPV065 glass, which was coated with a CTO transparent conductive layer and a thin high resistance transparent zinc tin oxide (ZTO) buffer layer. The window layer containing cadmium sulfide (CdS:O, 5 molar % oxygen in the CdS layer) was then deposited on the ZTO layer by DC sputtering followed by deposition of cadmium telluride (CdTe) layer at 550° C., and back contact formation.

### Example 1

### Method Of Manufacturing A Cadmium Telluride Photovoltaic Device Including A Magnesium-Containing Interlayer, Deposited By Atomic Layer Deposition

The method of making the photovoltaic device was similar to the Comparative Example 1, except a 4 nanometers thick magnesium oxide (MgO) capping layer was deposited by atomic layer deposition (ALD) on the CdS layer prior to the deposition of the CdTe layer.

### Example 2

### Method Of Manufacturing A Cadmium Telluride Photovoltaic Device Including A Magnesium-Containing Interlayer, Deposited By Sputtering

The method of making the photovoltaic device was similar to the Comparative Example 1, except a 6 nanometers thick elemental magnesium (Mg) capping layer was deposited by sputtering on the CdS layer, prior to the deposition of CdTe layer.

### Example 3

### Method Of Manufacturing A Cadmium Telluride Photovoltaic Device Including A Gadolinium-Containing Interlayer

The method of making the photovoltaic device was similar to the Comparative Example 1, except a 3 nanometers thick elemental gadolinium (Gd) capping layer was deposited by sputtering on the CdS layer, prior to the deposition of the CdTe layer.

As illustrated in FIGS. 5-7, the device performance parameters (normalized with respect to Comparative Example 1) showed improvement for the devices with an interlayer (Examples 1-3) when compared to the device without the interlayer (Comparative Example 1). Further, the devices with ALD-deposited interlayer (Example 1) showed greater than 20% efficiency increase when compared the device without an interlayer (Comparative Example 1). The photovoltaic devices including ALD-deposited interlayer (Example 1) further showed higher efficiencies and improved performance parameters when compared to the devices including sputtered interlayer (Example 2).

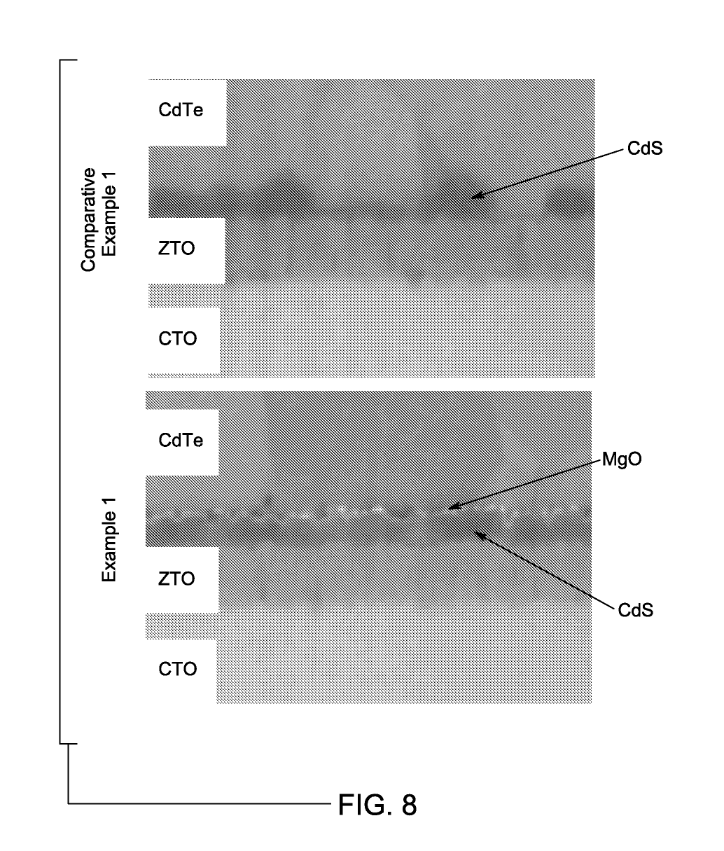

FIG. 8 shows the scanning electron micrographs of photovoltaic devices with or without the interlayer. As illustrated in FIG. 8, the micrograph of the photovoltaic device without the interlayer (Comparative Example 1) showed a non-uniform CdS layer structure, presumably because of CdS sublimation during one or more of the device fabrication steps. The micrograph of the photovoltaic device with the interlayer (Example 1), however, showed a more uniform CdS layer and a thin interlayer (including MgO) formed between the CdS layer and the CdTe layer.

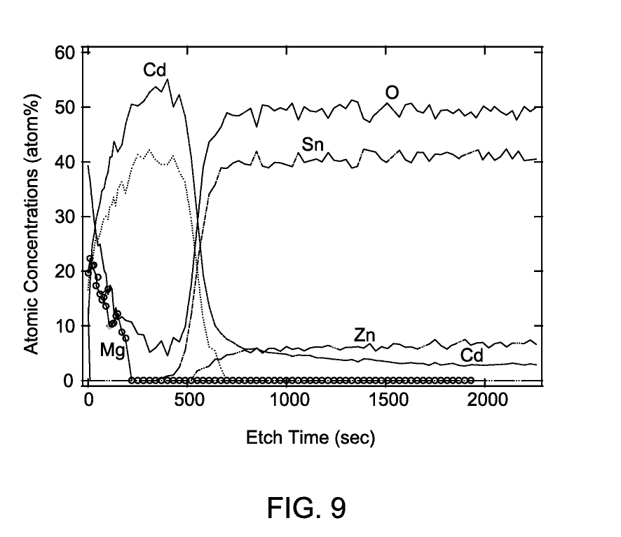

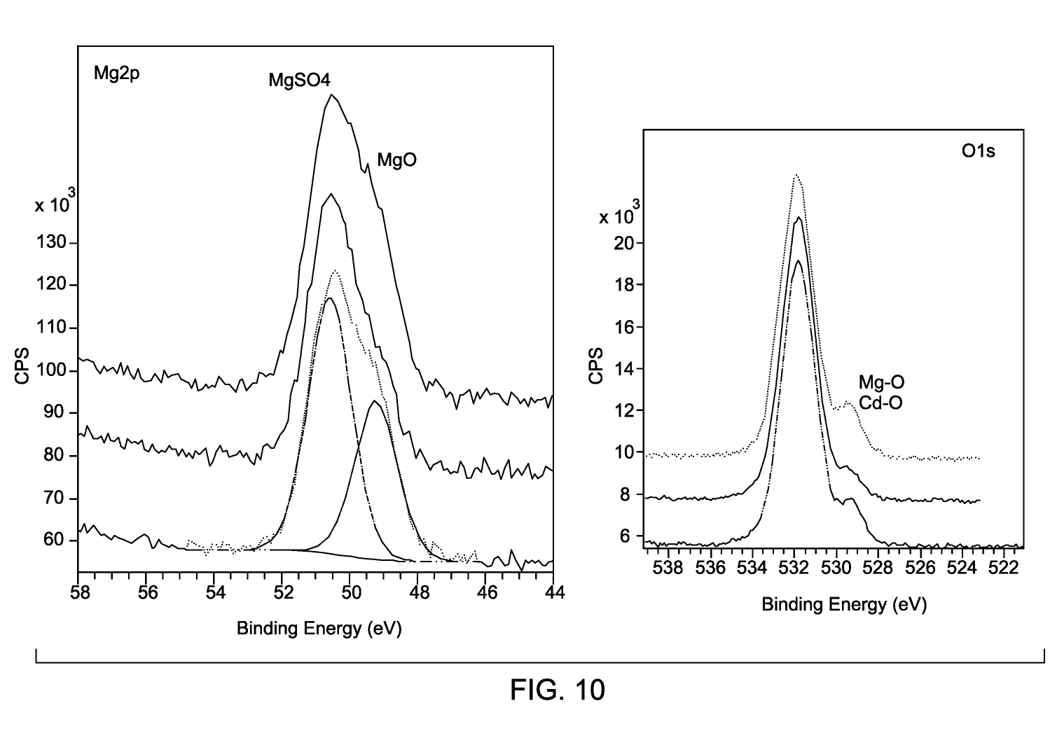

FIG. 9 shows the x-ray photoelectron spectroscopy (XPS) depth profiles of a photovoltaic device including an interlayer (Example 1), showing interaction between the MgO and the CdS layers only at the interface. FIG. 10 shows X-ray Photoelectron Spectroscopy (XPS) profiles of a photovoltaic device including an interlayer (Example 1). These XPS profiles suggest presence of oxide and sulfate phases in the interlayer.

The appended claims are intended to claim the invention as broadly as it has been conceived and the examples herein presented are illustrative of selected embodiments from a manifold of all possible embodiments. Accordingly, it is the Applicants' intention that the appended claims are not to be limited by the choice of examples utilized to illustrate features of the present invention. As used in the claims, the word “comprises” and its grammatical variants logically also subtend and include phrases of varying and differing extent such as for example, but not limited thereto, “consisting essentially of” and “consisting of.” Where necessary, ranges have been supplied; those ranges are inclusive of all sub-ranges there between. It is to be expected that variations in these ranges will suggest themselves to a practitioner having ordinary skill in the art and where not already dedicated to the public, those variations should where possible be construed to be covered by the appended claims.

It is also anticipated that advances in science and technology will make equivalents and substitutions possible that are not now contemplated by reason of the imprecision of language and these variations should also be construed where possible to be covered by the appended claims.

1. A photovoltaic device, comprising:
a first semiconductor layer;
a second semiconductor layer; and
an interlayer disposed between the first semiconductor layer and the second semiconductor layer, wherein the interlayer comprises gadolinium.

2. The photovoltaic device of claim 1, wherein at least a portion of the gadolinium is present in the interlayer in the form of gadolinium oxide.

3. The photovoltaic device of claim 2, wherein the interlayer further comprises a compound comprising gadolinium, sulfur, and oxygen.

4. The photovoltaic device of claim 2, wherein the interlayer further comprises gadolinium sulfate, gadolinium sulfite, gadolinium oxysulfate, or combinations thereof.

5. The photovoltaic device of claim 1, wherein the interlayer comprises GdₓMg₁₋ₓ, wherein x is an integer greater than 0 and less than 1.

6. The photovoltaic device of claim 1, wherein an average atomic concentration of the gadolinium in the interlayer is greater than about 50 percent.

7. The photovoltaic device of claim 1, wherein the interlayer has a thickness in a range from about 0.2 nanometers to about 20 nanometers.

8. The photovoltaic device of claim 1, wherein the first semiconductor layer comprises cadmium sulfide, oxygenated cadmium sulfide, zinc sulfide, cadmium zinc sulfide, cadmium selenide, indium selenide, indium sulfide, or combinations thereof.

9. The photovoltaic device of claim 1, wherein the second semiconductor layer comprises cadmium telluride, cadmium zinc telluride, cadmium sulfur telluride, cadmium manganese telluride, cadmium magnesium telluride, copper indium sulfide, copper indium gallium selenide, copper indium gallium sulfide, or combinations thereof.

10. A method, comprising:
(a) disposing a capping layer on a first semiconductor layer by atomic layer deposition, wherein the capping layer comprises magnesium, aluminum, zinc, nickel, gadolinium, or combinations thereof;
(b) disposing a second semiconductor layer on the capping layer; and
(c) forming an interlayer between the first semiconductor layer and the second semiconductor layer.

11. The method of claim 10, further comprising thermally processing a semiconductor assembly comprising the capping layer disposed on the first semiconductor layer, wherein the thermal processing is effected before the step (b).

12. The method of claim 10, wherein the step (c) is effected prior to, simultaneously with, or after the step (b).

13. The method of claim 10, wherein the capping layer comprises magnesium oxide, aluminum oxide, zinc oxide, nickel oxide, gadolinium oxide, or combinations thereof.

14. The method of claim 10, wherein the interlayer comprises magnesium oxide, aluminum oxide, zinc oxide, nickel oxide, gadolinium oxide, or combinations thereof.

15. The method of claim 14, wherein the interlayer further comprises a compound comprising a metal species, sulfur, and oxygen, wherein the metal species comprises magnesium, aluminum, zinc, nickel, gadolinium, or combinations thereof.

16. A method, comprising:
(a) disposing a metallic capping layer on a first semiconductor layer, wherein the metallic capping layer comprises magnesium, aluminum, zinc, nickel, gadolinium, or combinations thereof;
(b) disposing a second semiconductor layer on the metallic capping layer; and
(c) forming an interlayer between the first semiconductor layer and the second semiconductor layer.

17. The method of claim 16, further comprising thermally processing a semiconductor assembly comprising the capping layer disposed on the first semiconductor layer, wherein the thermal processing is effected before the step (b).

18. The method of claim 16, wherein the step (c) is effected prior to, simultaneously with, or after the step (b).

19. The method of claim 16, wherein the interlayer comprises magnesium oxide, aluminum oxide, zinc oxide, nickel oxide, gadolinium oxide, or combinations thereof.

20. The method of claim 19, wherein the interlayer further comprises a compound comprising a metal species, sulfur, and oxygen, wherein the metal species comprises magnesium, aluminum, zinc, nickel, gadolinium, or combinations thereof.

21. The method of claim 16, wherein the interlayer has a thickness in a range from about 0.2 nanometers to about 20 nanometers.

22. A photovoltaic device, comprising:
a first semiconductor layer;
a second semiconductor layer; and
an interlayer disposed between the first semiconductor layer and the second semiconductor layer, wherein the interlayer comprises a compound comprising a metal species, sulfur, and oxygen, wherein the metal species comprises magnesium, aluminum, zinc, nickel, gadolinium, or combinations thereof.
